(19) United States
(12) Patent Application Publication
(10) Pub. No.: US 2024/0162260 A1
(43) Pub. Date: May 16, 2024

(54) IMAGE SENSOR AND MANUFACTURING METHOD THEREOF

(71) Applicant: Powertech Technology Inc., Hsinchu County (TW)

(72) Inventor: Shao Chieh Lo, Hsinchu County (TW)

(73) Assignee: Powertech Technology Inc., Hsinchu County (TW)

(21) Appl. No.: 18/455,609

(22) Filed: Aug. 24, 2023

Related U.S. Application Data
(60) Provisional application No. 63/424,485, filed on Nov. 11, 2022.

(30) Foreign Application Priority Data
May 25, 2023 (TW) 112119534

(51) Int. Cl. H01L 27/146

(52) U.S. Cl. CPC H01L 27/14618; H01L 27/14683

(57) ABSTRACT

An image sensor includes a chip, a cover, a first dam layer, and a second dam layer. The chip has a sensing area. The cover covers the chip. The first dam layer and the second dam layer are located between the chip and the cover and surround the sensing area. The second dam layer is located between the first dam layer and the chip, and a width of the first dam layer is greater than a width of the second dam layer, and the first dam layer is extended to the sensing area by a distance. A manufacturing method of an image sensor is also provided.

### CROSS-REFERENCE TO RELATED APPLICATION

This application claims the priority benefit of U.S. application Ser. No. 63/424,485, filed on Nov. 11, 2022 and Taiwan application serial no. 112119534, filed on May 25, 2023. The entirety of the above-mentioned patent applications is hereby incorporated by reference herein and made a part of this specification.

### BACKGROUND OF THE INVENTION

### Field of the Invention

The invention relates to a sensor and a manufacturing method thereof, and in particular to an image sensor and a manufacturing method thereof.

### Description of Related Art

Image sensors have been widely used in various products in life today, and in image sensors, one factor compromising product reliability is optical defect caused by phenomena such as reflection. Therefore, how to effectively alleviate optical defect in image sensors and improve product reliability and performance is a real challenge.

### SUMMARY OF THE INVENTION

The invention provides an image sensor and a manufacturing method thereof that may effectively alleviate optical defect in the image sensor and improve product reliability and performance.

An image sensor of the invention includes a chip, a cover, a first dam layer, and a second dam layer. The chip has a sensing area. The cover covers the chip. The first dam layer and the second dam layer are located between the chip and the cover and surround the sensing area. The second dam layer is located between the first dam layer and the chip, a width of the first dam layer is greater than a width of the second dam layer, and the first dam layer is extended to the sensing area by a distance.

A manufacturing method of an image sensor of the invention includes the following steps: providing a package assembly, wherein the package assembly includes a first dam layer and a cover, and the first dam layer is formed on the cover; providing an element substrate, wherein the element substrate includes a base, a circuit structure, and a sensing area, and the circuit structure is located on the base and surrounds the sensing area; performing a bonding step via a second dam layer to bond the package assembly and the element substrate, wherein the second dam layer is located between the first dam layer and the element substrate, a width of the first dam layer is greater than a width of the second dam layer, and the first dam layer is extended to the sensing area by a distance.

Based on the above, in the image sensor of the invention, via the structural design of the dam layers, the width of the first dam layer is greater than the width of the second dam layer, and the first dam layer is extended to the sensing area by a distance. In this way, the effect of light shielding/anti-reflection may be achieved, such that optical defect in the image sensor may be effectively alleviated, and product reliability and performance may be improved.

In order to make the aforementioned features and advantages of the disclosure more comprehensible, embodiments accompanied with figures are described in detail below.

### BRIEF DESCRIPTION OF THE DRAWINGS

FIG. 1A to FIG. 1I are partial cross-sectional schematic views of a portion of a manufacturing method of an image sensor according to an embodiment of the invention.

FIG. 2 is a schematic partial cross-sectional view of an image sensor according to another embodiment of the invention.

FIG. 3A to FIG. 3E are partial cross-sectional schematic views of a portion of a manufacturing method of an image sensor according to another embodiment of the invention.

### DESCRIPTION OF THE EMBODIMENTS

Directional terms (e.g., up, down, right, left, front, back, top, bottom) as used herein are used pictorially for reference only and are not intended to imply absolute orientation.

Any method described herein is in no way intended to be construed as requiring performance of the steps thereof in a particular order, unless expressly stated otherwise.

The invention is more comprehensively described with reference to the figures of the present embodiments. However, the invention may also be implemented in various different forms, and is not limited to the embodiments in the present specification. The thickness, size, or magnitude of layers or regions in the drawings may be exaggerated for clarity. The same or similar reference numerals represent the same or similar elements and are not repeated in the following paragraphs.

It should be understood that although the terms “first”, “second”, “third”, etc. may be used herein to describe various elements, components, areas, layers, and/or portions, these elements, components, areas, and/or portions should not be limited by these terms. These terms are only used to distinguish one element, component, area, layer, or portion from another element, component, area, layer, or portion.

Unless otherwise stated, the term “between” used in this specification to define numerical ranges is intended to cover ranges equal to and between the stated endpoints. For example, if a size range is between a first value and a second value, the size range may cover the first value, the second value, and any value between the first value and the second value.

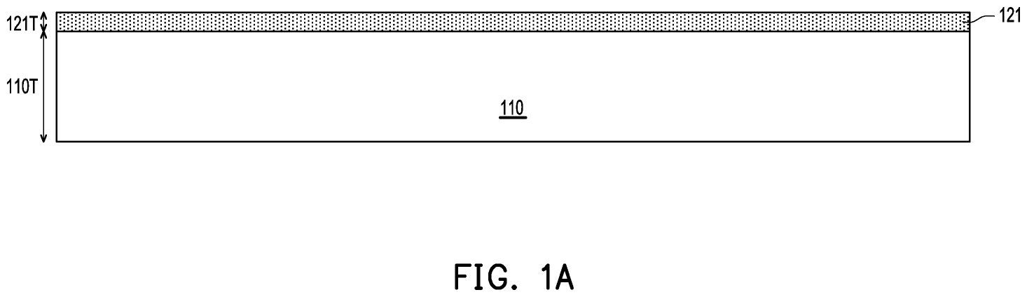

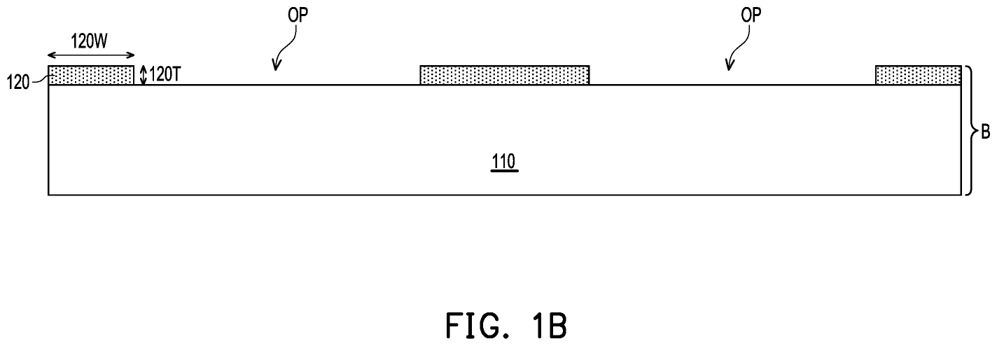

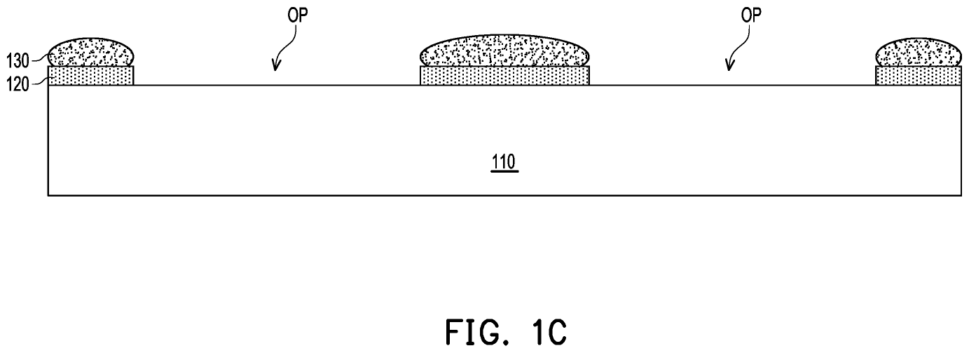

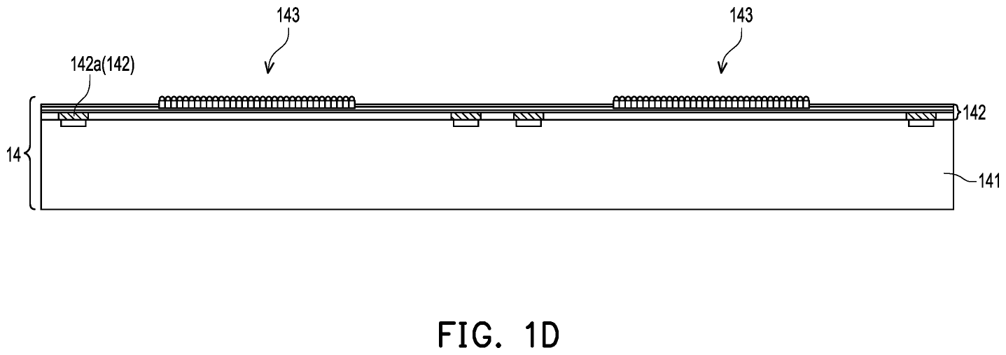

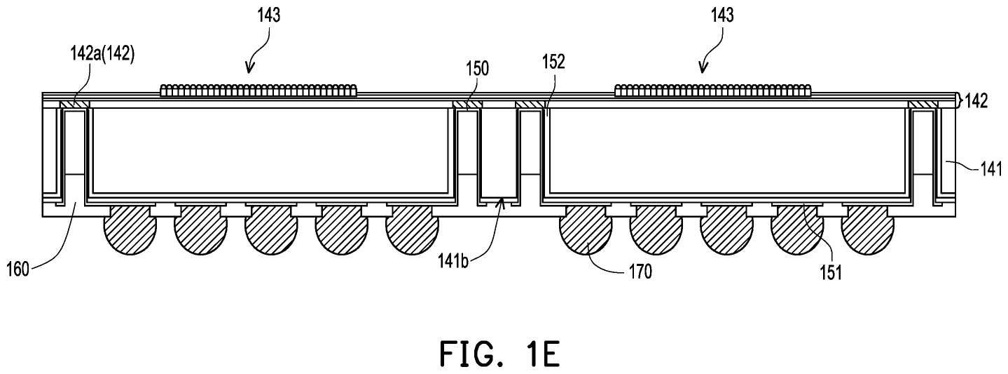

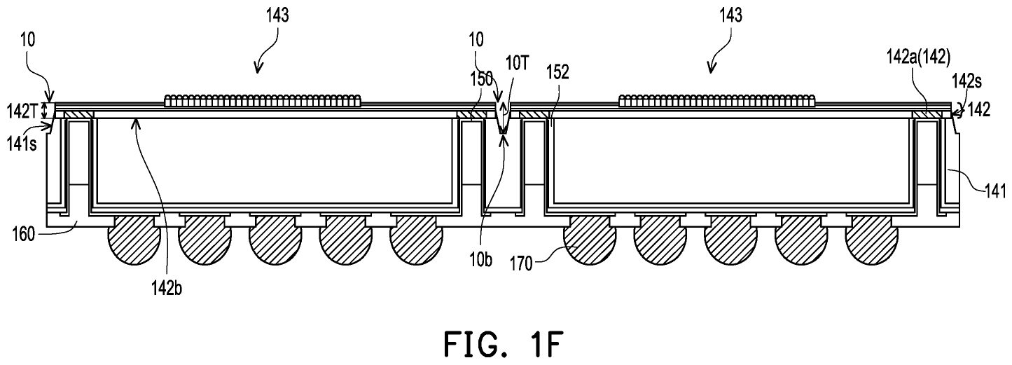

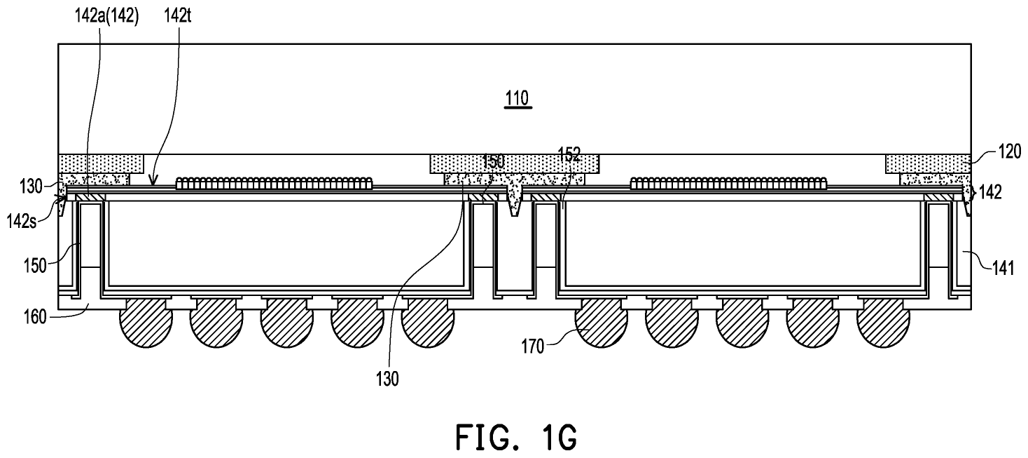

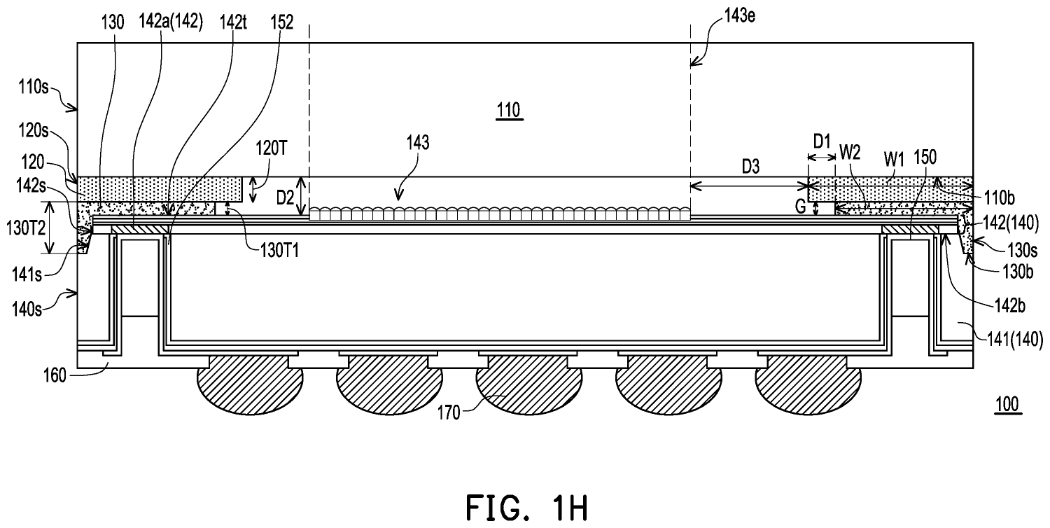

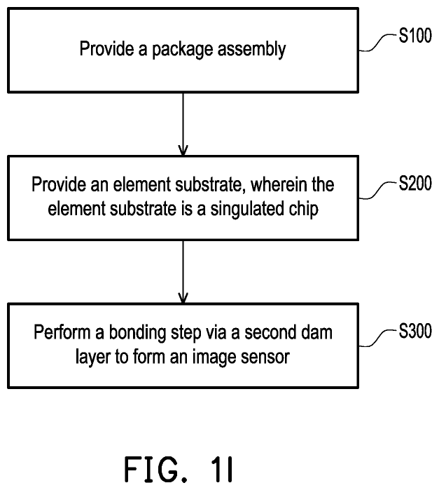

FIG. 1A to FIG. 1I are partial cross-sectional schematic views of a portion of a manufacturing method of an image sensor according to an embodiment of the invention. Referring to FIG. 1A, in the present embodiment, a manufacturing process of an image sensor may include the following steps. First, a cover 110 is provided, and a first dam material layer 121 is formed on the cover 110. For example, the first dam material layer 121 may be formed on the cover 110 comprehensively, and the first dam material layer 121 is, for example, a suitable high molecular polymer.

In some embodiments, the material of the cover 110 is a light-transmissible material, such as glass, and the first dam material layer 121 is a light-shielding and/or anti-reflection material, such as a polymer base material. For example, the first dam material layer 121 may be a photosensitive material, such as PBO, polyimide, BCB, or the like formed by coating, stencil printing, or lamination. In this way, a photolithography process may be performed on the first dam material layer 121 later, but the invention is not limited thereto.

In some embodiments, a thickness 110T of the cover 110 is less than or equal to 400 microns, and a thickness 121T of the first dam material layer 121 is greater than or equal to 5 microns, but the invention is not limited thereto.

Referring to FIG. 1B, a patterning process is performed on the first dam material layer 121 to form a first dam layer 120, wherein the first dam layer 120 has a plurality of openings OP exposing a portion of the cover 110, and the patterning process may be formed by a suitable process. For example, when the first dam material layer 121 is a photosensitive material, a photolithography process (exposure, development, and etching techniques) may be performed on the first dam material layer 121 and a curing process may be performed subsequently to form the first dam layer 120 with substantially fixed dimensions (such as a width 120W and a thickness 120T of the first dam layer 120) and shape. Therefore, the first dam layer 120 substantially does not cover the sidewalls of other layers due to extrusion deformation in the subsequent process, and also is not in contact with an element substrate 14 to be bonded subsequently, but the invention is not limited thereto. Here, the cover 110 and the first dam layer 120 may form a package assembly B.

In some embodiments, the thickness 120T of the first dam layer 120 is greater than or equal to 5 microns, but the invention is not limited thereto.

Referring to FIG. 1C, a second dam layer 130 is formed on the first dam layer 120, wherein the material of the first dam layer 120 and the second dam layer 130 may be a light-shielding and/or anti-reflection material, such as a polymer base material. For example, the second dam layer 130 is black adhesive. Moreover, the first dam layer 120 and the second dam layer 130 may be formed by a printing process (stencil printing, screen printing, or other suitable printing processes), but the invention is not limited thereto. It should be noted that, in the present embodiment, the second dam layer 130 may be firstly formed on the first dam layer 120, but the invention is not limited thereto. In other unillustrated embodiments, the second dam layer 130 may also be formed on the subsequent element substrate 14. Here, the second dam layer 130 may be compressible, so it may be deformed by extrusion during the subsequent bonding step, but the invention is not limited thereto.

In some embodiments, the second dam layer 130 is only formed on the first dam layer 120, so the second dam layer 130 is not directly in contact with the cover 110, but the invention is not limited thereto.

Referring to FIG. 1D, the element substrate 14 including a base 141, a circuit structure 142, and a sensing area 143 is provided, wherein the circuit structure 142 is located on the base 141 and surrounds the sensing area 143. In the present embodiment, the element substrate 14 may be a device wafer, so the subsequent bonding step may be wafer level bonding, but the invention is not limited thereto. In an unillustrated embodiment, the element substrate is a singulated chip, so the subsequent bonding step may be die level bonding, and no singulation process is performed after the bonding step.

In some embodiments, the circuit structure 142 may include a low-k material layer and a metal layer alternately stacked in a front end of line (FEOL) area, wherein a portion of the metal layer in the circuit structure 142 may be used as a landing pad 142a for electrical connection with a via 150 formed later. Here, the number of layers of the circuit structure 142 may be adjusted according to design requirements, which is not limited in the invention, and the layout design of the circuit structure 142 may also be adjusted according to design requirements. In addition, the sensing area 143 may be located on the active surface of the element substrate 14.

In some embodiments, the base 141 is, for example, a silicon substrate or other suitable base materials, which is not limited by the invention.

In some embodiments, the material of the low-k material layer and the material of the metal layer in the circuit structure 142 may be suitable dielectric and conductive materials respectively, which is not limited by the invention.

In some embodiments, the sensing area 143 may have a corresponding sensing element, such as a plurality of microlens structures, but the invention is not limited thereto.

Referring to FIG. 1E, the via 150 (extended in the vertical direction) is formed through the base 141, wherein the via 150 may be in direct contact with the landing pad 142a in the circuit structure 142 to form an electrical connection. For example, an opening exposing the landing pad 142a may be formed from a surface 141b of the base 141 opposite to the sensing area 143 by etching or other suitable methods. Next, a corresponding insulating layer (not shown) may be formed by deposition, etching, and/or other suitable methods, wherein the insulating layer may expose the landing pad 142a and cover the sidewall of the opening and the surface 141b of the base 141. Next, the corresponding conductive layer may be formed by deposition, plating, etching, and/or other suitable methods. In this way, the portion of the conductive layer and the corresponding insulating layer located in the opening may be referred to as the via 150, wherein when the base is a silicon base, the via 150 may be a through silicon via (TSV). Here, the insulating layer and the conductive layer may be any suitable material, which is not limited in the invention.

In some embodiments, an isolation layer 152 surrounding the via 150 may be further included to improve the electrical performance of the image sensor 100, wherein the isolation layer 152 may be oxide or polymer, but the invention is not limited thereto.

Next, a circuit layer 151 electrically connected to the via 150 may be formed on the surface 141b of the base 141. Then, a passivation layer 160 covering the surface 141b of the base 141 and filled in the opening of the via 150 may be formed, wherein the passivation layer 160 has a plurality of openings exposing the circuit layer 151. Conductive terminals 170 are then formed in/on the openings of the passivation layer 160, so the landing pad 142a and the conductive terminals 170 may be electrically connected to the circuit layer 151 via the via 150. Here, the passivation layer 160 may not completely fill the opening of the via 150 to form a hollow hole, but the invention is not limited thereto.

In some embodiments, the material and the process of forming the circuit layer 151 are similar to the conductive layer in the via 150, the passivation layer 160 is formed by epoxy resin, green paint (solder mask), or other suitable insulating materials via yellow light process (exposure lithography technique), and the conductive terminals 170 are solder balls formed by a ball mounting process or a reflow process, but the invention is not limited thereto.

In an unillustrated embodiment, the conductive terminals 170 may also be formed after a subsequent bonding step, which is not limited by the invention.

It should be noted that although the via 150 shown in FIG. 1E is rectangular (the included angle between the via 150 and the position in the horizontal direction is 90 degrees), in an unillustrated embodiment, the via 150 may also be trapezoidal (the included angle between the via 150 and the position in the horizontal direction is, for example, greater than or equal to 85 degrees and less than 90 degrees).

Referring to FIG. 1F, a pre-saw process is performed to remove a portion of the circuit structure 142 and form a groove 10, wherein the groove 10 may expose an outer sidewall 142s of the circuit structure 142, but the invention is not limited thereto.

In the present embodiment, the pre-saw process may further remove a portion of the base 141, so that a bottom surface 10b of the groove 10 is extended below a bottom surface 142b of the circuit structure 142. Therefore, a depth 10T of the groove 10 is at least greater than a thickness 142T of the circuit structure 142. For example, when the thickness 142T of the circuit structure 142 is about 10 μm, the depth 10T of the groove is about 15 μm, so the groove 10 may expose the outer sidewall 142s of the circuit structure 142 and an outer sidewall 141s of the base 141. It should be noted that the pre-saw process does not cut through the base 141.

In some embodiments, the pre-saw process is sawing with a rotating blade or a laser beam, so the groove 10 has a gradually changing size (such as a change in width that is wide at the top and narrow at the bottom). In this way, when performing secondary sawing (for example, singulation process), sawing yield may be improved, but the invention is not limited thereto.

Referring to FIG. 1G, the bonding step is performed via the second dam layer 130 to bond the package assembly B (including the cover 110 and the first dam layer 120) with the element substrate 14 (including the base 141, the circuit structure 142, and the sensing area 143). Therefore, the second dam layer 130 may be located between the first dam layer 120 and the element substrate 14.

In the present embodiment, the second dam layer 130 may be squeezed and filled into the groove 10 under the influence of gravity during the bonding step. Therefore, the second dam layer 130 may be extended from a top surface 142t of the circuit structure 142 to cover the outer sidewall 142s of the circuit structure 142 along the groove 10, but the invention is not limited thereto.

Referring to FIG. 1H, since the element substrate 14 of the present embodiment may be a device wafer, the bonding step further includes performing a singulation process to form a plurality of image sensors 100, wherein the element substrate 14 may be singulated into a plurality of chips 140, and each of the chips 140 may include the corresponding base 141, circuit structure 142, and sensing area 143. Here, the number of the image sensors 100 formed by the singulation process may be determined according to actual design requirements, which is not limited by the invention.

In some embodiments, the singulation process is, for example, performed by a rotary blade or a laser beam. It should be noted that, in some other embodiments, the step shown in FIG. 1I may also be performed. First, a package assembly is provided (step S100), and then, an element substrate is provided, wherein the element substrate is a singulated chip (step S200), and then, a bonding step is performed via a second dam layer to form an image sensor (step S300). That is, the image sensor is formed after the bonding step, omitting the singulation process, wherein the components in the package assembly and the element substrate may be similar to those described in the above various embodiments. For example, after the structure shown in FIG. 1E or FIG. 1F is formed, a sawing process is performed on the structure with a rotary blade or a laser beam to form a plurality of separated single chips. Therefore, in the bonding step, the cover and the separated chips are bonded in a one-to-one manner. In this case, the forming of the first dam layer 120 and the second dam layer 130 in the middle portion (the portion where subsequent sawing is performed) in FIG. 1C may be omitted. In other words, in FIG. 1C, only the first dam layer 120 and the second dam layer 130 on the left and right side edges are formed, but the invention is not limited thereto.

After the above process, the manufacture of the image sensor 100 of the present embodiment may be substantially completed. The image sensor 100 of the present embodiment includes the chip 140, the cover 110, the first dam layer 120, and the second dam layer 130, wherein the cover 110 covers the chip 140, the first dam layer 120 and the second dam layer 130 are located between the chip 140 and the cover 110 and surround the sensing area 143 of the chip 140, and the second dam layer 130 is located between the first dam layer 120 and the chip 140. Moreover, in the image sensor 100 of the present embodiment, via the structural design of the dam layers, a width W1 of the first dam layer 120 is greater than a width W2 of the second dam layer 130, and the first dam layer 120 is extended to the sensing area 143 by a distance D1. In this way, the effect of light shielding/anti-reflection may be achieved, such that optical defect in the image sensor 100 may be effectively alleviated, and product reliability and performance may be improved. Here, the distance D1 may be greater than or equal to 0.1 μm, but the invention is not limited thereto.

For example, since the light enters the sensing area 143 from the cover 110 above, there is often a reflection issue in the sensing area 143. Therefore, the reflection issue may be effectively alleviated by the structural design in which the first dam layer 120 is extended to the sensing area 143 by the distance D1 and staggered.

In some embodiments, the first dam layer 120 and the second dam layer 130 may be different polymer materials, so they may exhibit different properties. For example, the transmittance of the first dam layer 120 is at least less than 70%, and the transmittance of the second dam layer 130 is at least less than 50%, but the invention is not limited thereto.

In some embodiments, the light transmittance of at least one of the first dam layer 120 and the second dam layer 130 is less than or equal to 30%. For example, the light transmittance of both the first dam layer 120 and the second dam layer 130 is less than or equal to 30%. Therefore, by selecting materials with low transmittance, the light shielding/anti-reflection effect may be more reliably achieved, and the occurrence probability of optical defect may be reduced, but the invention is not limited thereto. Here, the light transmittance may be obtained at a wavelength of 400 nm to 900 nm.

In an embodiment, the reflectance of both the first dam layer 120 and the second dam layer 130 may be less than 0.3%, but the invention is not limited thereto.

It should be noted that the first dam layer 120 and the second dam layer 130 may be any suitable polymer material, as long as they fall within the range of the above transmittance and reflectance, they all belong to the scope of the invention.

In some embodiments, the material of the first dam layer 120 is different from the material of the second dam layer 130. For example, the first dam layer 120 includes a photosensitive material, and the second dam layer 130 does not include the photosensitive material, but the invention is not limited thereto.

In some embodiments, the water absorption of at least one of the first dam layer 120 and the second dam layer 130 is less than or equal to 1%. For example, the water absorption of both the first dam layer 120 and the second dam layer 130 is less than or equal to 1%, but the invention is not limited thereto.

In the present embodiment, after the singulation process is performed, an outer sidewall 110s of the cover 110, an outer sidewall 120s of the first dam layer 120, an outer sidewall 130s of the second dam layer 130 are aligned with an outer sidewall 140s of the chip 140, and the second dam layer 130 is extended from the top surface 142t of the circuit structure 142 to cover the outer sidewall 142s of the circuit structure 142. Therefore, a bottom surface 130b of the second dam layer 130 may be lower than the bottom surface 142b of the circuit structure 142, so that the second dam layer 130 may protect the low-k material layer and the conductive layer in the circuit structure 142 to reduce cracking of the circuit structure 142 in a stress environment and increase product reliability.

Moreover, since the pre-saw process may form a microcrack structure on the outer sidewall 141s of the base 141, the second dam layer 130 may simultaneously have a blocking effect when covering the outer sidewall 141s of the base 141 to reduce the probability of the microcrack structure extending to the inside of the chip 140, so that product reliability may be further improved, but the invention is not limited thereto.

In some embodiments, there is a gap G between the first dam layer 120 and the top surface 142t of the circuit structure 142 of the chip 140. For example, the gap G may be equal to the thickness of the second dam layer 130, wherein the gap G may be greater than or equal to 5 microns, but the invention is not limited thereto.

In the present embodiment, since the groove 10 has a gradually changing size, the extending portion of the second dam layer 130 at the outer sidewall 142s of the circuit structure 142 also has a gradually changing size. Therefore, the second dam layer 130 has a non-uniform thickness, such as a minimum thickness 130T1 and a maximum thickness 130T2 shown in FIG. 1H, and the gap G may be equal to the minimum thickness 130T1, but the invention is not limited thereto.

In some embodiments, a distance D2 between the bottom surface 110b of the cover 110 and the top surface 142t of the circuit structure 142 is equal to the sum of the thickness 120T of the first dam layer 120 and the thickness (e.g., the minimum thickness 130T1) of the second dam layer 130. Here, the distance D2 from the bottom surface 110b of the cover 110 to the top surface 142t of the circuit structure 142 is greater than or equal to 10 microns, but the invention is not limited thereto.

In some embodiments, the landing pad 142a, the first dam layer 120, and the second dam layer 130 are overlapped in the orthographic projection direction. Therefore, the landing pad 142a may be protected by the low-transmittance first dam layer 120 and second dam layer 130. When light comes down from above, the light does not penetrate and irradiate the landing pad 142a to form a reflection. Therefore, the performance of the sensing area 143 may be further improved, but the invention is not limited thereto.

In some embodiments, the thickness 120T of the first dam layer 120 is greater than the thickness of the second dam layer 130 (such as the maximum thickness 130T2), wherein the maximum thickness 130T2 of the second dam layer 130 is greater than or equal to 5 microns, but the invention is not limited thereto, and the thickness 120T of the first dam layer 120 may also be equal to the thickness of the second dam layer 130 (such as the maximum thickness 130T2).

In some embodiments, a distance D3 between the inner sidewall of the first dam layer 120 and an edge 143e of the sensing area 143 is greater than or equal to 5 microns, but the invention is not limited thereto.

In some embodiments, the image sensor 100 is a complementary metal oxide semiconductor image sensor (CMOS image sensor; CIS), but the invention is not limited thereto.

It must be noted here that the following embodiments follow the reference numerals and a portion of the content of the above embodiments, wherein the same or similar reference numerals are used to represent the same or similar elements, and the description of the same technical content is omitted. For the description of omitted portions, reference may be made to the above embodiments, and the following embodiments will not repeat the omitted portions.

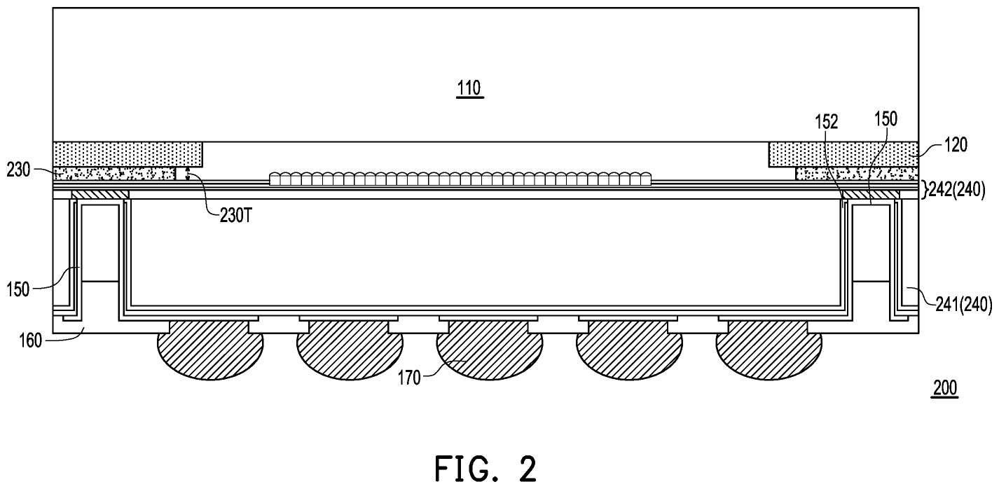

FIG. 2 is a schematic partial cross-sectional view of an image sensor according to another embodiment of the invention. Please refer to FIG. 2, compared with the image sensor 100 of FIG. 1H, an image sensor 200 of the present embodiment is not subjected to a pre-saw step. That is, a base 241 and a circuit structure 242 of a chip 240 are not partially removed, so a second dam layer 230 does not need to cover the outer sidewall of the circuit structure 242. In addition, since the second dam layer 230 has no downward extending portion, the second dam layer 230 has a uniform thickness 230T, but the invention is not limited thereto.

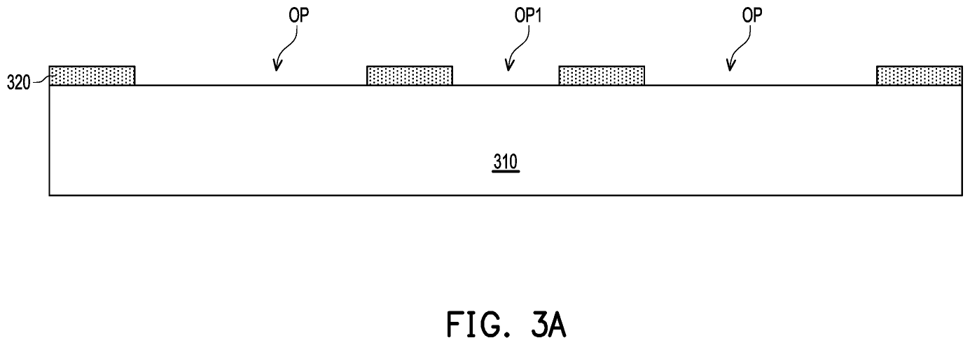

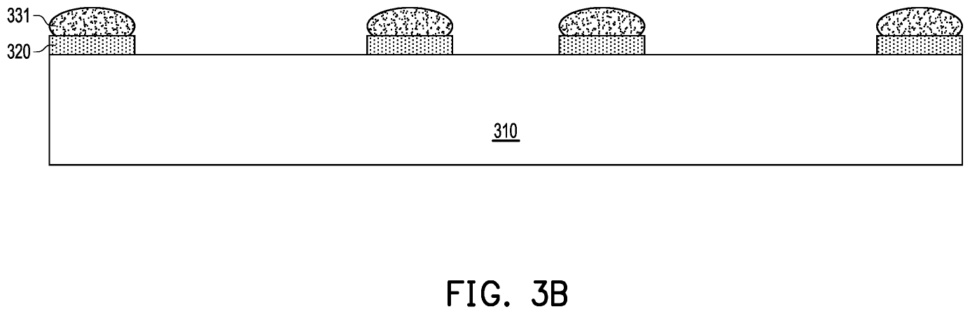

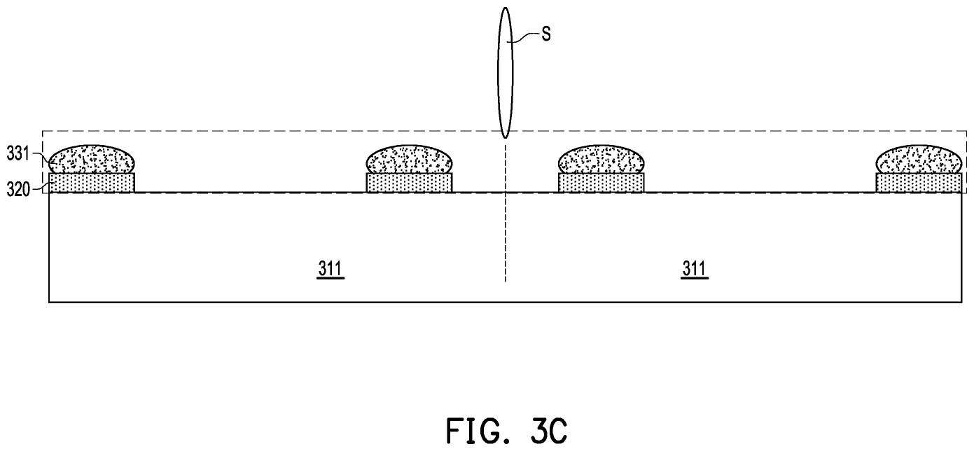

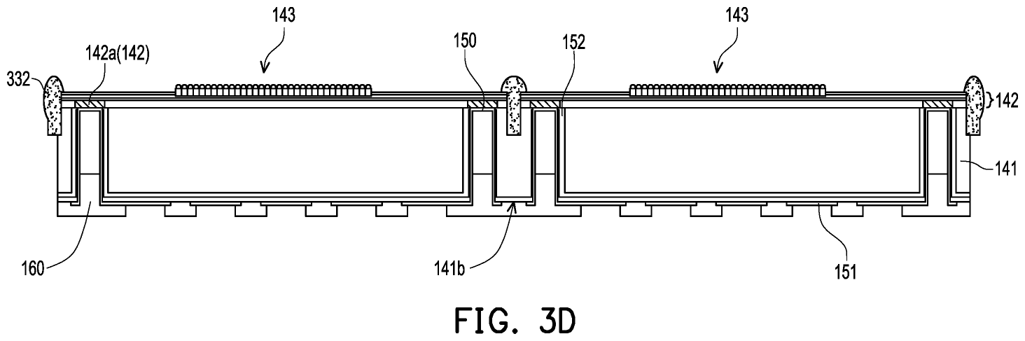

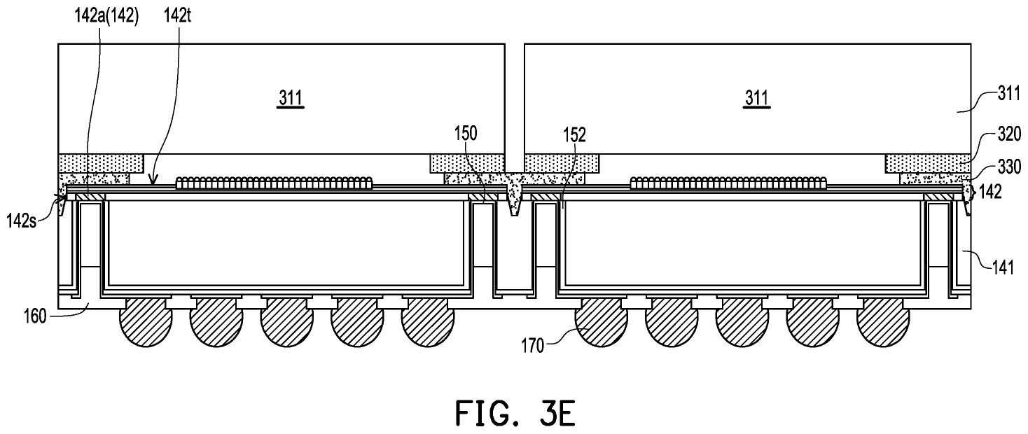

FIG. 3A to FIG. 3E are partial cross-sectional schematic views of a portion of a manufacturing method of an image sensor according to another embodiment of the invention.

Please refer to FIG. 3A, which is similar to FIG. 1B. The difference is that a first dam layer 320 formed on a cover 310 of the present embodiment further includes an opening OP1 after the patterning process to correspond to the position of the cover 310 to be sawed later.

Referring to FIG. 3B, a dam material layer 331 is correspondingly formed on the patterned first dam layer 320, wherein the relative relationship between the first dam layer 320 and the dam material layer 331 is similar to the relative relationship between the first dam layer 120 and the second dam layer 130 in FIG. 1C.

Please refer to FIG. 3C, a sawing process is performed to separate the cover 310 into a plurality of portions. For example, as shown in FIG. 3C, a plurality of covers 311 may be separated by a blade S, wherein the size of the cover 311 of each separated portion may correspond to the size of the single chip 140 in the image sensor 100.

Please refer to FIG. 3D, similar to FIG. 1F, the difference is that the present embodiment further includes forming a dam material layer 332 in the groove 10 before the bonding step, wherein the material and the forming method of the dam material layers 331 and 332 may be similar to the second dam layer 130, or may be different from the second dam layer 130 and formed by other suitable materials and forming methods, which are not limited in the invention.

Please refer to FIG. 3E, the plurality of covers 311 separated in FIG. 3C and the first dam layer 320 and the dam material layer 331 thereon are bonded onto the other dam material layer 332, and the dam material layer 331 and the dam material layer 332 are mixed to form a second dam layer 330 after bonding, wherein there may be a gap between adjacent covers 311 to expose a portion of the second dam layer 330. Then, a singulation process may be performed to singulate the chip 140 and form the structure of the image sensor 100.

It should be noted that, the upper limit/lower limit values not described above may both be suitably selected according to actual design requirements.

Based on the above, in the image sensor of the invention, via the structural design of the dam layers, the width of the first dam layer is greater than the width of the second dam layer, and the first dam layer is extended to the sensing area by a distance. In this way, the effect of light shielding/anti-reflection may be achieved, such that optical defect in the image sensor may be effectively alleviated, and product reliability and performance may be improved.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. An image sensor, comprising:
a chip having a sensing area;
a cover covering the chip;
a first dam layer; and
a second dam layer, wherein the first dam layer and the second dam layer are located between the chip and the cover and surround the sensing area, the second dam layer is located between the first dam layer and the chip, a width of the first dam layer is greater than a width of the second dam layer, and the first dam layer is extended to the sensing area by a distance.

2. The image sensor of claim 1, wherein a light transmittance of at least one of the first dam layer and the second dam layer is less than or equal to 30%.

3. The image sensor of claim 1, wherein a material of the first dam layer is different from a material of the second dam layer.

4. The image sensor of claim 3, wherein the first dam layer comprises a photosensitive material, and the second dam layer does not comprise the photosensitive material.

5. The image sensor of claim 1, wherein a water absorption of at least one of the first dam layer and the second dam layer is less than or equal to 1%.

6. The image sensor of claim 1, wherein an outer sidewall of the cover, an outer sidewall of the first dam layer, an outer sidewall of the second dam layer are aligned with an outer sidewall of the chip.

7. The image sensor of claim 1, wherein the chip comprises a circuit structure surrounding the sensing area, and there is a gap between the first dam layer and a top surface of the circuit structure.

8. The image sensor of claim 7, wherein the second dam layer is extended from the top surface of the circuit structure to cover an outer sidewall of the circuit structure.

9. The image sensor of claim 8, wherein a bottom surface of the second dam layer is lower than a bottom surface of the circuit structure.

10. The image sensor of claim 8, wherein the second dam layer has a gradually changing size at an extending portion of the outer sidewall of the circuit structure.

11. The image sensor of claim 1, wherein the chip comprises a landing pad, and the landing pad, the first dam layer, and the second dam layer are overlapped in an orthographic projection direction.

12. The image sensor of claim 1, wherein a thickness of the first dam layer is greater than a thickness of the second dam layer.

13. A manufacturing method of an image sensor, comprising:
providing a package assembly, wherein the package assembly comprises a first dam layer and a cover, and the first dam layer is formed on the cover;
providing an element substrate, wherein the element substrate comprises a base, a circuit structure, and a sensing area, and the circuit structure is located on the base and surrounds the sensing area;
performing a bonding step via a second dam layer to bond the package assembly and the element substrate, wherein the second dam layer is located between the first dam layer and the element substrate, a width of the first dam layer is greater than a width of the second dam layer, and the first dam layer is extended to the sensing area by a distance.

14. The manufacturing method of the image sensor of claim 13, wherein the step of forming the first dam layer comprises: forming a photosensitive material on the cover, and performing a photolithography process on the photosensitive material.

15. The manufacturing method of the image sensor of claim 13, further comprising, before the bonding step, performing a pre-saw process to remove a portion of the circuit structure and form a groove, so that the second dam layer is squeezed and filled into the groove during the bonding step.

16. The manufacturing method of the image sensor of claim 15, wherein the pre-saw process further removes a portion of the base so that a bottom surface of the groove is extended below a bottom surface of the circuit structure.

17. The manufacturing method of the image sensor of claim 16, wherein the groove exposes an outer sidewall of the circuit structure and an outer sidewall of the base.

18. The manufacturing method of the image sensor of claim 13, wherein the element substrate is a device wafer, and after the bonding step, a singulation process is further performed to singulate a plurality of chips.

19. The manufacturing method of the image sensor of claim 13, wherein the element substrate is a singulated chip, and a singulation process is not performed after the bonding step.

20. The manufacturing method of the image sensor of claim 13, further comprising, before the bonding step, sawing the cover to form a plurality of portions.
